(19) United States
(12) Patent Application Publication
(10) Pub. No.: US 2009/0095706 A1
(43) Pub. Date: Apr. 16, 2009

(54) Selective patterning of Multilayer Systems for OPV in a roll to roll process

(76) Inventors: Jens Hauch, Heroldsberg (DE); Christoph Brabec, Linz (AT)

Correspondence Address: FISH & RICHARDSON PC, P.O. BOX 1022, MINNEAPOLIS, MN, 55440-1022, US

(21) Appl. No.: 12/253,085

(22) Filed: Oct. 16, 2008

Related U.S. Application Data
(60) Provisional application No. 60/999,169, filed on Oct. 16, 2007.

(51) Int. Cl. C23F 1/02

(52) U.S. Cl. 216/13

(57) ABSTRACT

Methods of using etching pastes to form a pattern on an electrode of a solar cell, as well as related articles, systems, and components, are disclosed.

### CROSS REFERENCE TO RELATED APPLICATIONS

This application claims priority to U.S. Provisional Application Ser. No. 60/999,169, filed Oct. 16, 2008, the contents of which are hereby incorporated by reference.

### SUMMARY

The disclosure features methods of using screen printed etching pastes that are heat activated to form a pattern on the electrodes of a solar cell. The process of etching a pattern can be performed in 3 steps:

a) Screen printing an etching paste

b) Heating

c) Washing and Drying

The process can be considerably easier and cheaper than traditional photolithographic processes, although it is limited in resolution to several 10s of micrometers.

One purpose of the methods described in this disclosure is to create electrically insulated areas on plastic film substrates that are used to define separated solar cells, i.e. to pattern the electrodes of the solar cell. An advantage is that the patterning methods outlined may be designed in such a way that only conducting layers of a multilayer stack are patterned, and such that printed and non-printed layers can be used to stop the etching process selectively. This can enable applications for patterning both the top and the bottom electrodes that involve few process steps and should be low cost as well as environmentally friendly.

### DESCRIPTION OF DRAWINGS

FIG. 1 is a cross-sectional view of a photovoltaic module.

FIG. 2 is cross-sectional view of a photovoltaic module including a plurality of interconnected photovoltaic cells.

FIG. 3 illustrates an embodiment of etching a bottom electrode by using an etching paste.

FIG. 4 illustrates an embodiment of etching a bottom electrode on an etch stop layer by using an etching paste.

FIG. 5 illustrates an embodiment of etching a bottom electrode by using an etching paste, the bottom electrode being coated with a photoactive layer prior to the etching.

FIG. 6 illustrates an embodiment of etching a bottom electrode on an etch stop layer by using an etching paste, the bottom electrode being coated with a photoactive layer prior to etching.

FIG. 7 illustrates an embodiment of etching a top electrode by using an etching paste.

FIG. 8 illustrates an embodiment of etching a top electrode on an etch stop layer by using an etching paste.

Like reference symbols in the various drawings indicate like elements.

### DETAILED DESCRIPTION

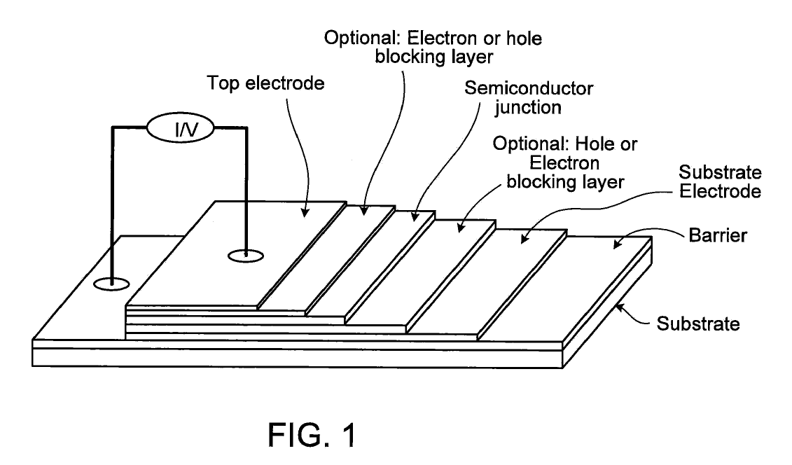

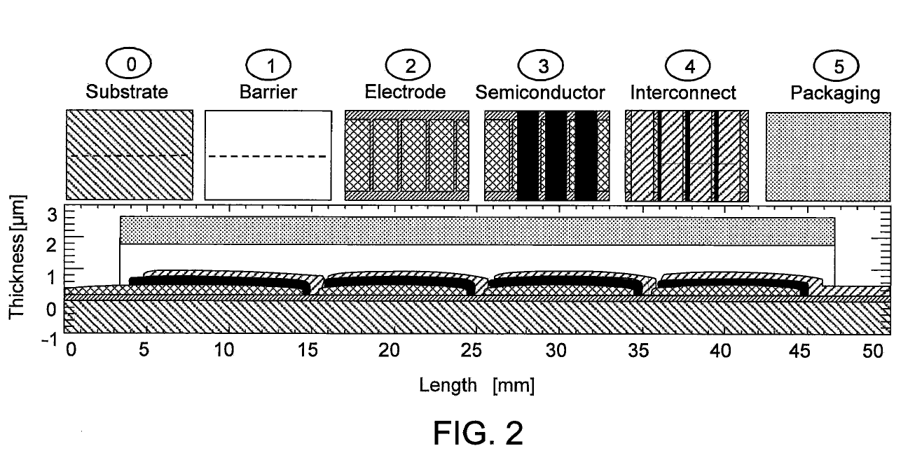

The general structure of an organic solar cell is shown in FIG. 1. One advantage of organic photovoltaics is that monolithically interconnected modules can be manufactured in the fashion shown in FIG. 2. To create monolithically interconnected solar cell modules on a substrate it is necessary to have two patterned electrodes: 1) the substrate based electrode 2) the top electrode. In addition to the patterned electrodes an interconnect between the top and the bottom electrode is needed to finish the module in the so called Z-interconnect scheme.

In order to ensure a good lifetime of organic solar cells commonly inorganic barrier layers are used to protect the organic material from water and oxygen. It is advantageous to have this barrier layer directly underneath the substrate electrode, although this is not necessary.

The general procedure for creating a module is
i) deposition of barrier and electrode on the substrate. Typical materials for the barrier layers are sputtered SiOx, AlOx or ZnSnOx. These may be single layers, or multiple layers separated by organic smoothing layers. The electrode is typically made from transparent conductive oxides like e.g. ITO or AZO. The electrode also may be made up of multiple conductive layers, through the combination of thin metal and TCO layers. All the layers are usually deposited by combinations of sputtering and PE-CVD (plasma enhanced CVD) in a multi-target chamber such that electrode and barrier may be manufactured in a single machine, although that is not required.
ii) Patterning of the bottom electrode. Processes that may be used here are mechanical patterning with various methods, laser patterning and lithography. Mechanical and laser patterning are non selective, and therefore typically will destroy the properties of a barrier layer. Lithographic etching is a process that comprises many steps, but has the advantage that it can be used to selectively pattern individual layers.
iii) Deposition of electron blocking layer, active layer and hole blocking layer by e.g. printing process
iv) Deposition of the back electrode by either printing or evaporation. Printing offers the advantage of a patterned deposition. Evaporation is potentially lower cost and in the current status provides better functionality. However evaporation through a shadow mask a roll to roll process is difficult.

The direct deposition of a printable etching material, that can selectively pattern electrode layers may be used both in step i) and in step iv) of the production process. In step i) the etching material is used to selectively pattern the conducting electrode materials like TCO or metal layers without removing the barrier layers composed of SiOx, AlOx, ZnSnOx or other barrier materials. The etchant therefore is selective to TCO or metal over SiOx, AlOx, ZnSnOx. An additional etch stop layer of an etch resistant material, e.g. ZnO, may also be introduced between the barrier and the electrode layers to stop the etching process.

In step iv) the etching material is used to selectively pattern the top electrode (deposited e.g. by thermal evaporation or sputtering) that is made of Ag, Al or another metal, or of a TCO layer that is sputtered on top of the OPV cell. The etching process is stopped either by the bottom electrode material, or it is stopped by an etch stop layer that is deposited by printing or another method.

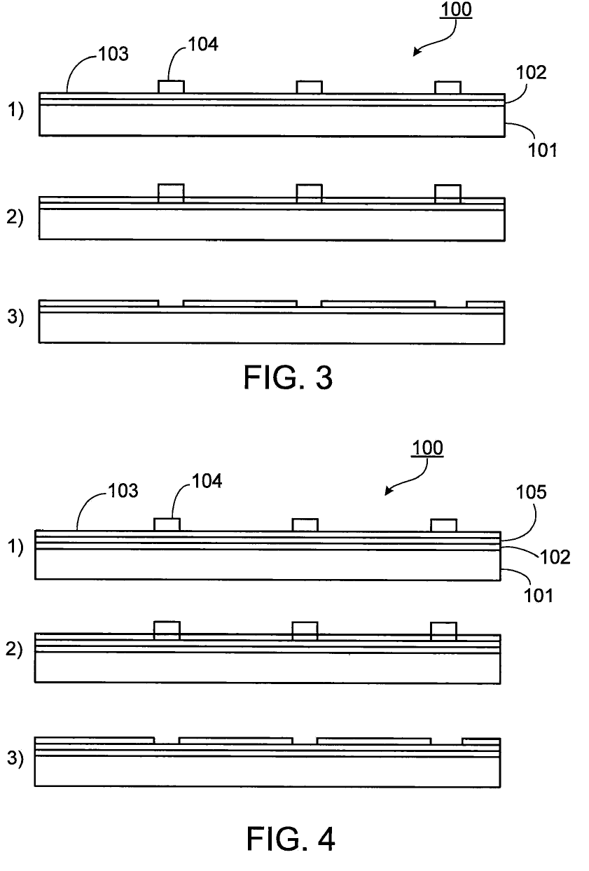

In FIGS. 3-8, several examples outline the processing steps necessary to create a patterned electrode in an article 100 and monolithically interconnected modules using printable etching pastes.

Some examples for the materials of the individual layers are listed below, but the materials are not limited to this set of materials:

i) Barrier layer: This may single layers of SiOx, AlOx, ZnSnOx or any other Oxide layer with a barrier function. Non-transparent metal layers may also be used as a barrier layer. In addition barrier layers may consist of organic/inorganic multilayer systems where in between the barrier layers of metal or Oxide polymer layers are applied to improve the barrier properties of the individual layers. The final layer may be organic or inorganic.

ii) TCO or metal electrode: This may be any type of TCO like ITO, Al:ZnO, doped TiO2 or metal like Al, Ag, Ti, or multilayer stacks of ITO/metal/ITO (IMI) or any other combination of dielectric/metal/dielectric or stacks of multiple metals (e.g. NiCr/Al/NiCr), where the number of layers is not limited to three.

iii) Active layers: This are the light absorbing layers responsible for the energy conversion. This includes the semiconductor layer which may be composed of a blend of an p-type of semiconductor (i.e. P3HT, PPV) and an n-type semiconductor (i.e. PCBM) but is not limited to these materials. The active layers may also consist of multiple layers of non-blended materials, including metal interlayers, which may be required to form a tandem cell. The active layers may also include selective interlayers (hole blocking or electron blocking layers) like e.g. Pedot or TiO2, but not limited to the mentioned materials.

iv) Electrode material: This could be composed of any type of metal applied by evaporation or any other type of process. It could also be a printed material, like a silver filled ink or a conductive carbon compound. It may be formed as a multiplayer combination of various materials (i.e. Chrome/Gold or silver ink/conductive carbon) or it may be applied in the form of a grid or metal fingers to provide light transmission, or it may be composed of any other conductive material, transparent or opaque, which provides a surface conductivity of <50 Ohm/sq.

v) Etch Stop—this is a material specifically chosen to stop the etching process in a particular location. This may be an inorganic material like, but not limited to, SiO2 or a metal, or a printed polymer layer (cross-linked or not) that is resistant to etching.

### Variation 1

Variation 1 as shown in FIG. 3 is performed in three stages:

1) printing of etching paste 104 on an electrode 103, which is located on a barrier layer 102 on a substrate 101;

2) heating and etching paste 104 with the barrier layer 102 serving as the etch stop;

3) rinsing and drying article 100 to form a patterned electrode 103.

This variation has the advantage of few process steps, and no extra use of materials.

### Variation 2

Variation 2 as shown in FIG. 4 is performed in three stages:

1) printing etching paste 104 on an electrode 103, which is disposed above an etch stop 105 that is disposed on a barrier layer 102 on a substrate 101.

2) heating and etching the etching paste 104 with the etch stop 105 stopping the etching process;

3) rinsing and drying article 100 to form a patterned electrode 103.

This variation has the advantage of few process steps. In comparison to Variation 1, the etch stop and barrier function are decoupled, leading to more freedom in the material selection.

### Variation 3

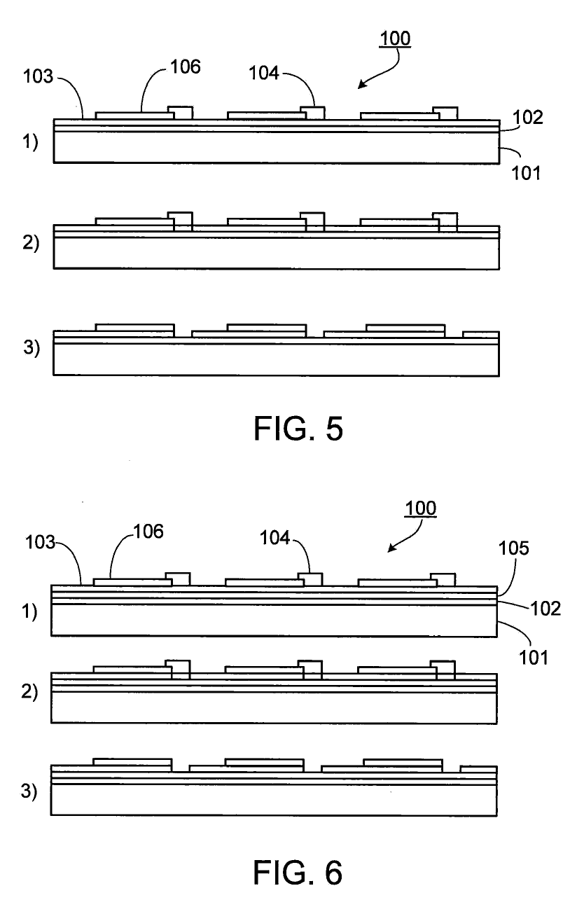

Variation 3 as shown in FIG. 5 or FIG. 6 is performed in three stages:

1) printing etching paste 104 on electrode 103, which is disclosed on a barrier layer 102 on a substrate 101, where some or all of a photoactive layer 106 has already been applied;

2) heating and etching the etching paste 104, with the barrier layer 102, or an optional etch stop layer 105 (see FIG. 6), stopping the etching process (photoactive layer 106 defining an edge of the etched area);

3) rinsing and drying article 100 to form patterned electrode 103.

This variation has the advantage of few process steps. In comparison to Variation 1 and 2 there are two advantages. Some or all of the active layers are printed on a pristine, un-patterned substrate, which means that all contamination with dirt or particles from the patterning process are avoided, and higher layer qualities for the active layers may be achieved. In addition to this, the use of the active layer to define one of the edges of the etched area may aid in increasing the area utilized for solar power conversion, as well as reducing the likelihood of shunts at the edge.

### Variation 4

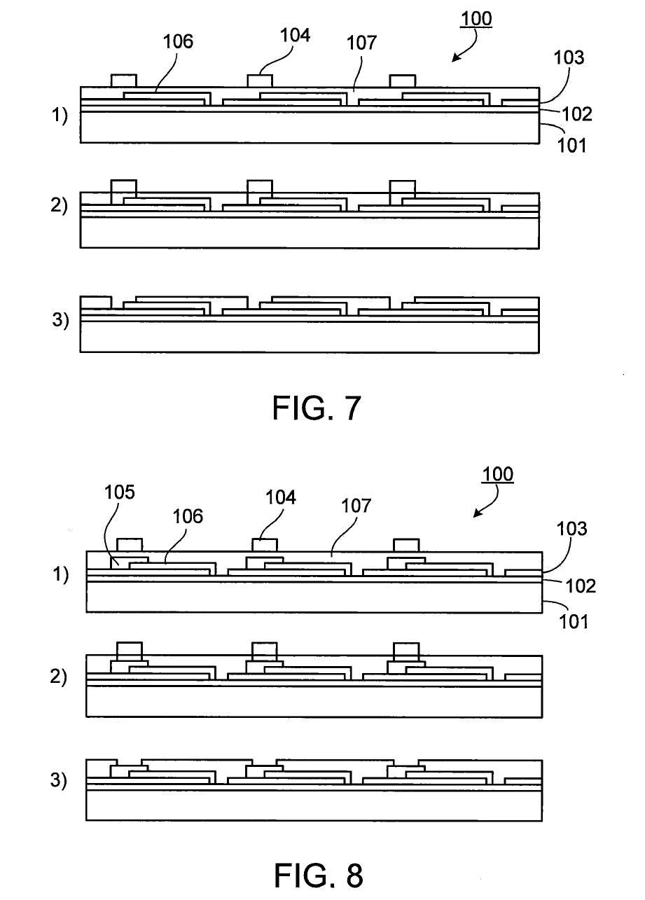

Variation 4 as shown in FIG. 7 is performed in three stages:

1) printing etching paste 104 on metallized top electrode 107 of a fully formed solar cell stack;

2) heating and etching the etching paste 104, with the bottom electrode and/or the active layer of the cell serving as the etch stop; and

3) rinsing and drying article 100 to form patterned electrode 107.

This variation has the advantage of few process steps, and no extra use of materials. In addition it enables a full area deposition (via e.g. evaporation or sputtering) of the top electrode material onto the full stack.

### Variation 5

Variation 5 as shown in FIG. 8 is performed in three stages—

1) printing etching paste 104 metalized top electrode 107 on a fully formed solar cell stack, which includes a patterned etch stop layer 105 as part of the full stackup.

2) heating and etching the etching paste 104, with the etch stop 105 stopping the etching process; and

3) rinsing and drying article 100 to form patterned electrode 107.

This variation has the advantage of few process steps. The functions of the active layer and the solar cell/electrode are decoupled, allowing for a large choice of materials.

### Remarks Applying to all Variations:

The variations presented here show only a limited subset of what is possible through the use etching pastes. There are many further variations possible, particularly when printed etch stop layers are included.

What is claimed is:

1. A method, comprising:
applying an etch paste onto an electrode to form an article; and
treating the article for form a patterned electrode.

2. The method of claim 1, wherein treating the article comprises heating the etch paste.

3. The method of claim 1, wherein treating the article further comprises removing the etch paste after heating the etch paste.

4. The method of claim 1, further comprising incorporating the patterned electrode into a photovoltaic cell.
